(19) United States
(12) Patent Application Publication
(10) Pub. No.: US 2026/0016516 A1
(43) Pub. Date: Jan. 15, 2026

(54) ELECTRICITY METER MANAGEMENT OF CIRCUIT BREAKER OPEN-SWITCH EVENTS

(71) Applicant: Itron, Inc., Liberty Lake, WA (US)

(72) Inventors: Prasad Deshpande, Bengaluru (IN); Sahana Vadwa, Bangalore (IN)

(21) Appl. No.: 18/773,028

(22) Filed: Jul. 15, 2024

(51) Int. Cl. G01R 22/06

(52) U.S. Cl. CPC G01R 22/068

(57) ABSTRACT

Techniques for smart electricity meter operation and management of open-switch events are described. In an example, a voltage value of a transformer-side of a service site is measured. Power consumption at the service site is measured. Based at least in part on the voltage value being non-zero and the power consumption being zero, it is determined that an open-switch event occurred. That is, because the utility company is supplying typical voltage to the electricity meter, and because the power consumption is zero, a breaker switch may have tripped. Accordingly, a customer of the service site is notified of the open-switch event.

### BACKGROUND

Power outages can result from acts of nature, equipment failure, electrical grid overload, and other causes. However, to a customer inside their residence (i.e., the service site) a power failure and a tripped circuit breaker or blown fuse can appear very similar. In some cases, the customer may wait for service to be restored, only to realize that the power loss was a tripped circuit breaker. In other cases, a customer may leave the residence to look for signs of power use in neighboring service sites. And further, a customer may investigate the electrical system at the service site in a manner that constitutes a safety hazard. In such cases, easier access to more and better information would be welcome.

### BRIEF DESCRIPTION OF THE DRAWINGS

The detailed description is described with reference to the accompanying figures. In the figures, the left-most digit(s) of a reference number identifies the figure in which the reference number first appears. The same numbers are used throughout the drawings to reference like features and components. Moreover, the figures are intended to illustrate general concepts, and not to indicate required and/or necessary elements.

FIG. 1 is a block diagram showing portions of an example electricity grid, including aspects of power transmission, data processing, and smart electricity meter management of circuit breaker open-switch events.

FIG. 2 is a block diagram showing example detail of portions of a smart electricity meter, including features used for management of circuit breaker open-switch events.

FIG. 3 is a block diagram showing an example electricity service site, including example relationships between an example smart electricity meter configured for management of circuit breaker open-switch events, a circuit breaker box, miniature circuit breaker (MCB) devices, and electrical appliances and/or electrical loads.

FIG. 4 is a flow diagram showing example operation of a smart electricity meter, including example techniques for distinguishing a utility company power outage event and an open-switch event (e.g., an open circuit breaker switch).

FIG. 5 is a flow diagram showing first example techniques for learning circuit characteristics within an electricity service site, and for managing MCB devices.

FIG. 6 is a flow diagram showing second example techniques for learning circuit characteristics within an electricity service site, and for managing MCB devices.

FIG. 7 is a flow diagram showing further example techniques for responding to, and providing notice of, MCB open-switch events.

FIG. 8 is a flow diagram showing further example techniques for responding to, and providing notice of, MCB open-switch events.

### DETAILED DESCRIPTION

### Overview

This disclosure describes techniques for smart utility meter (e.g., smart electricity meter or simply “smart meter”) operation, techniques for management of circuit breaker open-switch events, and techniques for distinguishing circuit breaker open-switch events from power outage events. In a first example, a voltage value of a transformer-side of a service site is measured. Additionally, at least one of a power value or a current value of at least one circuit of the service site is measured and/or calculated. Based at least in part on the voltage value being non-zero and the power value or the current value of the at least one circuit being zero, the system (e.g., smart meter) may determine that an open-switch event may have occurred. That is, because the utility company is supplying a non-zero or typical voltage to the electricity meter, and because the current value is zero, the system can determine that a breaker switch may have tripped. Accordingly, a customer of the service site can be notified of the possible open-switch event. This prevents the customer from wrongly assuming that there was a utility failure (e.g., a power outage or “blackout”), when in fact the circuit breaker at the customer's service site has a tripped switch.

In a second example, disaggregation of loads may be used to associate appliances with circuits of a circuit breaker, and may be used to avoid over-stressing more heavily used circuits. In the example, a load measured by the smart metering device can be disaggregated to determine one or more constituent devices of the load (i.e., devices and their respective loads are identified as parts of the total measured load). Once identified, the loads of individual devices (e.g., appliances) may be associated with particular circuits of a circuit breaker box. Once that association has been made, the customer may be provided with information regarding the use of particular devices and particular circuits, wherein each circuit is associated with a switch in a circuit breaker box. This information can be used by the customer to locate appliances on circuits more effectively and safely, thereby reducing circuit overloads and breaker tripping. In an example of associating devices and circuits, occasional circuit breaker open-switch events can, over time, be used to associate devices with particular circuits of a circuit breaker box. Power usage may be recognized as the sum of a combination of appliances operating concurrently. A load disaggregation process recognizes differently sized changes in load at a service, and over time, associates the changes with the activity of respective appliances. Appliances that use one or more discrete power levels can be most easily identified. In some examples, commonly used appliances and their associated commonly seen power usage rates can be looked for in a changing load of a service site. In the event of a circuit breaker switch opening, a specific load (that has previously been associated with a particular appliance or a sum of appliances) may be recognized. The recognition may be made based on cessation of the sum of loads of known devices when the breaker switch trips. That is, when the load of a known appliance suddenly ends due to a circuit breaker open-switch event, that load can be associated with that switch. Accordingly, information associating devices (e.g., appliances, etc.) and circuit breaker circuits can be provided to the customer and used by the customer to locate appliances on circuits more effectively and safely, thereby reducing circuit overloads and breaker tripping.

### Example System and Techniques

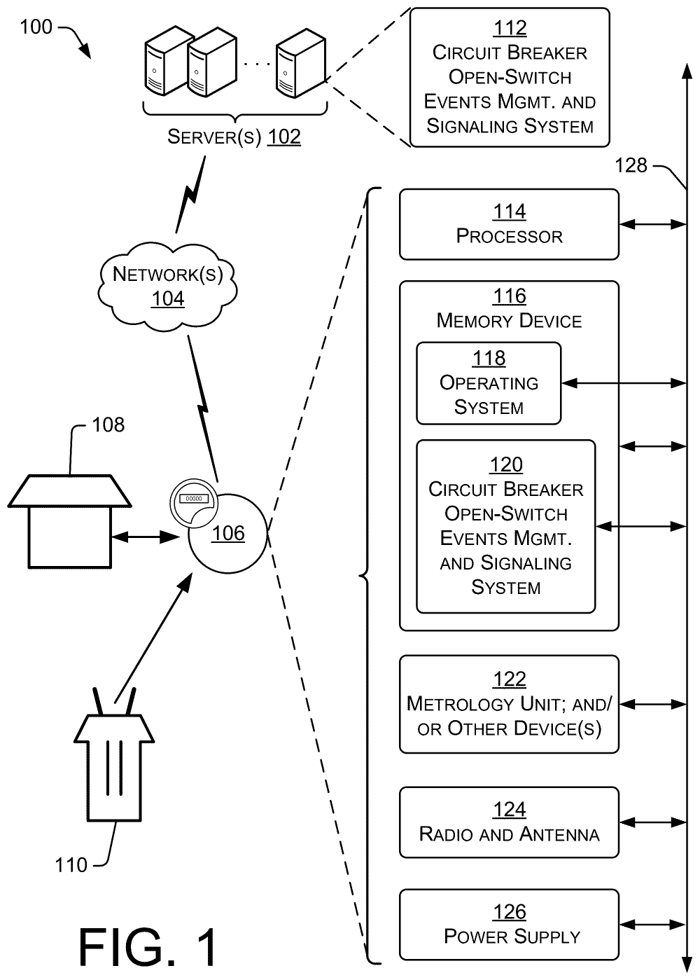

FIG. 1 shows features of an example electricity grid 100, including operation of an electricity meter configured to detect and process circuit breaker open-switch events. While the techniques are shown as implemented by an electricity meter, some or all of the techniques may be additionally or alternatively implemented by other devices, including a smart circuit breaker box, a smart transformer, or servers of an electric utility company or other cloud-based computing devices.

The example electricity grid 100 includes central office or “cloud” server(s) 102 and networks 104. The networks 104 may include one or more of the internet, utility company proprietary network(s) using radio, powerline communications (PLC), mesh networks, star networks, etc.

A smart meter 106 (e.g., smart electricity meter) serves a service site 108, and is representative of many such meters and sites, which may number in the thousands or hundreds of thousands. In the example shown, the meter is a smart meter and is in communication with the central office server(s) 102 through the network 104. A transformer 110 is configured to serve one or more customers, and provides low voltage service to the service site 108, which is measured by the smart meter 106. The transformer 110 is representative of many such transformers, which may number in the thousands or hundreds of thousands.

A system configured to detect and process circuit breaker open-switch events may be located on the central office server(s) 102 and/or on the smart meter 106. For purposes of illustration, FIG. 1 shows both examples, wherein a system 112 is located on the central office server(s) 102, and wherein a signaling system 120 is located on the smart meter 106.

In a first example, the system configured to detect and process circuit breaker open-switch events may be located entirely on the smart meter 106. Accordingly, the techniques, components, and algorithms described herein are operable on the smart meter 106. Referring to the example of FIG. 1, the circuit breaker open-switch event management and signaling system 120 is located on the smart meter 106.

As a second example, some or all of the system configured to detect and process circuit breaker open-switch events may be located on utility company server(s) 102. Referring to the example of FIG. 1, at least portions of the circuit breaker open-switch events management and signaling system 112 are located on the server(s) 102. In some examples, the portions of the system operational on the server(s) 102 may provide complex machine-learning, artificial intelligence, and/or algorithmic support, while other portions of the system may be operable on the smart meter 106.

In the example shown, the smart meter 106 includes a processor 114 and memory device 116. The memory device 116 may include software programs, that when executed by the processor 114, perform useful functions. In the example of FIG. 1, software applications are shown, including an operating system 118 and the circuit breaker open-switch events management and signaling system 120.

The smart meter 106 may include metrology device(s) 122 to measure consumption of electricity. The smart meter 106 may include a radio 124 which may include or be coupled to an antenna. Additionally or alternatively, the smart meter may include a PLC modem or other communications device. The smart meter 106 may also include a power supply 126 to provide regulated direct current (DC) at appropriate voltages. Accordingly, the power supply provides regulated DC at prescribed voltage levels for operation of the processor 114, the memory device 116, the radio 124, and/or other devices. A bus, printed circuit board, wiring harness, and/or other circuit connectivity device(s) 128 may be used to connect the processor 114, the memory device 116, the metrology device(s) 122, the radio 124, and the power supply 126.

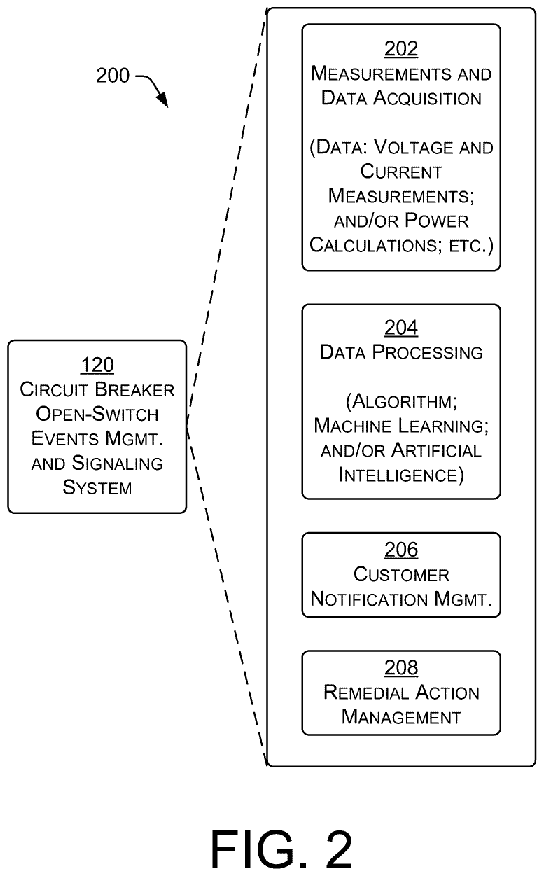

FIG. 2 shows an example 200 of portions of a smart electricity meter, including software configured to operate the circuit breaker open-switch events management and signaling system 120. In the example 200, the software is divided (strictly for purposes of showing example functionality and not as a required configuration) into three main subroutines. A subroutine for measurements and data acquisition 202 obtains data from the metrology device(s) 122 and maintains databases, such as for the results of disaggregation calculations, time-series of voltage and current measurements, appliance configurations that resulted in tripped breakers, associations of appliances and/or other devices and particular circuits of a circuit breaker box, etc.

A subroutine for data processing 204 is configured to operate deterministic algorithms and/or machine-learning (e.g., artificial intelligence) models. Such tools allow the circuit breaker open-switch events management and signaling system 120 to recognize open-switch events, the causes of such events, and to proactively provide information to customers at the service site to assist in the avoidance of interruptions in service. In an example, a smart meter can examine data trends to identify and predict potential issues before they lead to circuit breaker open-switch events. By utilizing machine learning algorithms and predictive analytics, smart meters can anticipate and prevent failures, improve overall grid reliability, increase safety, and reduce maintenance costs. In an example illustration, if switching on the hair dryer in a bathroom between 7 AM and 9 AM daily frequently results in a circuit breaker open-switch event, the user can be notified in advance that such actions may result in a circuit breaker open-switch event, i.e., a “breaker trip.” This notification may be based at least in part on recognition by the smart meter that other devices (based on their known loads) are currently in operation (or recently in operation) on the same circuit. By referencing devices on the circuit that may contribute to an open-switch event, the user is able to distribute device more evenly among available circuits.

A subroutine for customer notification management 206 interfaces with the customer, such as by messaging a mobile device of the customer. Alternatively, an in-home device (IHD) may receive the message. Such devices may utilize any available communication technology, such as Zigbee, cellular, light weight machine to machine (LwM2M), and others. Accordingly, information about tripped breakers, miniature circuit breaker (MCB) open-switch events, combinations of appliances resulting in tripped breakers, etc., is communicated to the customer. Information regarding methods, addresses, phone numbers, etc., to be used to contact the customer may also be used and maintained.

A remedial action manager 208 can be utilized to send a signal to the circuit breaker or MCB to cause a reset the circuit breaker switch. The signal may be sent upon instruction by the customer and/or when sufficient time has passed for the customer to have reduced the potential load on the circuit. In an alternative example utilizing an electrically resettable circuit breaker, the circuit breaker may be reset responsive to a message sent by the utility company and/or by the smart meter with or without intervention by the customer.

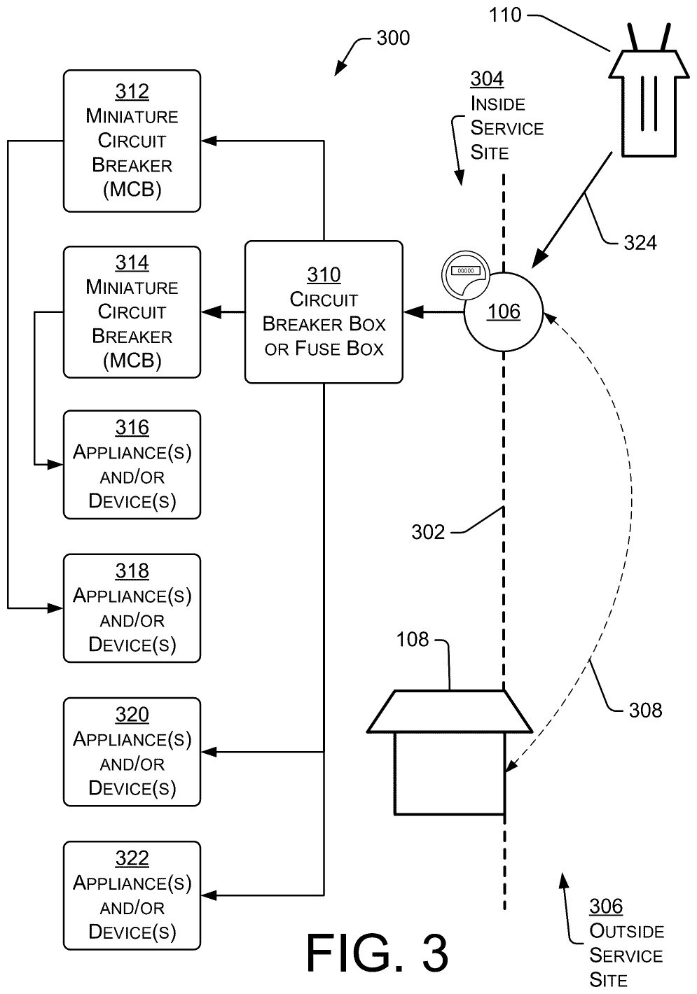

FIG. 3 shows an example electricity service site 300, including example relationships between an example smart electricity meter configured for management of circuit breaker open-switch events, a circuit breaker box, miniature circuit breaker (MCB) devices, and electrical appliances and/or electrical loads.

The example electricity service site 300 includes a service site 108 with a smart meter 106. A transformer 110 provides low voltage (e.g., 110 volts or 220 volts) to the smart meter 106 over transmission lines 324. An artificial boundary 302 divides areas inside 304 the service site 300 from areas outside 306 the service site. Dashed line 308 shows that the smart meter 106, while shown remotely from the service site 108 is actually attached to the residence. A circuit breaker box 310 (or fuse box) is configured with multiple circuits. Advantageously, the circuit breaker box 310 allows the current (or power) supplied to any one circuit to be limited, while allowing the service site to consume much greater quantities of current (or power). In the example shown, the circuit breaker box 310 provides separate wiring circuits to miniature circuit breakers (MCBs) 312, 314, which in turn provide power to a plurality of appliances and/or devices 316, 318, respectively. Accordingly, the MCBs 312, 314 are able to limit the current provided to their respective appliances and/or devices 316, 318. Additionally, the MCBs may provide data to the smart meter 106 and/or to the circuit breaker box 310. In the example, the circuit breaker box 310 provides wiring circuits to each group of appliances and/or devices 320, 322. As shown in FIG. 3, the smart meter 106 interfaces with the circuit breaker box 310 and the transformer 110. Accordingly, the smart meter 106 is in a position to determine if an electrical failure (no voltage, no current) is the result of an open-switch event of the circuit breaker box 310 or a failure of the electrical grid (i.e., no voltage at the transformer 110). Additionally, the smart meter 106 is in communication with the MCBs, and is able to determine (such as by data exchange and communication) if one or more MCB is associated with an open-switch event.

### Example Methods

In some examples, the techniques discussed herein may be implemented by one more processors accessing software defined on one or more memory devices. The processor(s) and memory device(s) may be located on an electricity meter and/or a cloud-based server (e.g., a server of a utility company). If the functionality is distributed, software may reside on both the electricity meter and the server.

In other examples of the techniques discusses herein, the methods of operation may be performed by one or more application specific integrated circuits (ASIC) or may be performed by a general-purpose processor utilizing software defined in computer readable media. In the examples and techniques discussed herein, the memory device 116 may comprise computer-readable media and may take the form of volatile memory, such as random-access memory (RAM) and/or non-volatile memory, such as read only memory (ROM) or flash RAM. Computer-readable media devices include volatile and non-volatile, removable, and non-removable media implemented in any method or technology for storage of information such as computer-readable instructions, data structures, program modules, or other data for execution by one or more processors of a computing device. Examples of computer-readable media include, but are not limited to, phase-change memory (PRAM), static random-access memory (SRAM), dynamic random-access memory (DRAM), other types of random access memory (RAM), read-only memory (ROM), electrically erasable programmable read-only memory (EEPROM), programmable read-only memory (PROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transitory medium that can be used to store information for access by a computing device.

As defined herein, computer-readable media includes non-transitory media. Computer-readable media does not include transitory media, such as modulated data signals and carrier waves, and/or other information-containing signals.

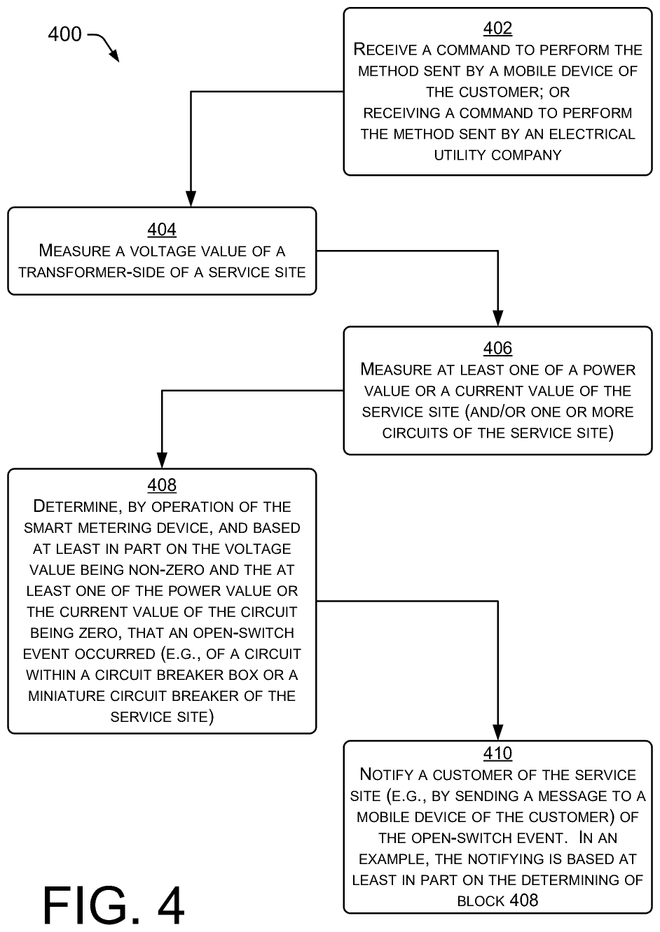

FIG. 4 shows method 400 to operate features of a smart electricity meter. In the example, techniques distinguish a utility company power outage event from an open-switch event (e.g., an open circuit breaker switch or open MCB switch). The method 400 may be performed by the smart meter 106 described in FIGS. 1-3. In an example method 400, a voltage value of a transformer-side of a service site is measured. Additionally, at least one of a power value or a current value of at least one circuit of the service site is measured and/or calculated. Based at least in part on the voltage value being non-zero and the power value or the current value of the at least one circuit being zero, it is determined that an open-switch event may have occurred. That is, because the utility company is supplying a non-zero voltage to the electricity meter, and because the current value is zero, a breaker switch may have tripped. Accordingly, a customer of the service site is notified of the open-switch event. This prevents the customer from wrongly assuming that there was a utility failure (e.g., a “power outage”), when in fact the circuit breaker has a tripped switch.

At block 402, a command to perform the method 400 may be received at a smart electricity meter (e.g., the smart meter 106 of FIG. 1) or other device. In a first embodiment, the command is sent by a mobile device of the customer. The customer may be experiencing a power outage at their location, and wants to know the cause (e.g., is the problem unique to their site, or is the problem a broader regional power outage). Additionally or alternatively, the command to perform the method 400 may be sent by an electrical utility company and received at the smart meter 106. The utility company may have noticed a decrease in consumption at the utility service site, and may wish to proactively resolve the situation and/or notify the customer of the situation so as not to be erroneously blamed for the outage, when in fact the outage is caused by the customer's circuit breaker box. Accordingly, the utility company may initiate the method 400 to thereby determine the facts and inform the customer of the situation.

At block 404, a voltage value of a transformer-side of a service site is measured. This is essentially a measurement of the transformer output voltage. Referring to the example of FIG. 1, the metrology device(s) 122 of the smart meter 106 measures the voltage supplied by the transformer 110. Pairs of voltage and current measurements can be made in the course of measuring power consumed at the service site, and over time, the energy consumed at the service site.

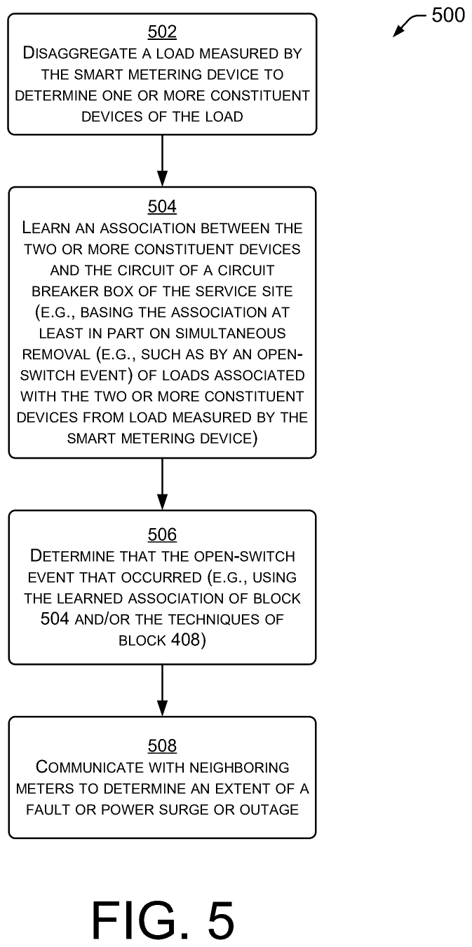

At block 406, a power value or a current value of the service site (and/or at least one circuit of the circuit breaker box of the service site) is measured. Referring to FIG. 3, the smart meter 106 is configured to make voltage and current measurements of the power consumed at the service site. Accordingly, the smart meter 106 is configured to measure a sum of the current flowing through all circuits of the circuit breaker box 310. Accordingly, in one example the power or current is measured for the entire service site. Additionally or alternatively, as will be discussed with respect to FIG. 5 and elsewhere, the current flow within individual circuits of a circuit breaker box may be determined or approximated.

At block 408, the existence of an open-switch event may be determined, such as by operation of the smart metering device 106. In an example, the determination is based at least in part on the voltage value being non-zero and the at least one of the power value or the current value of the circuit being zero. That is, if the transformer 110 is providing typical voltage, and yet the power consumption is zero (in one circuit, a plurality of circuits, or all circuits of the circuit breaker box 310) then it may be reasonable to suspect an open-switch event or condition.

At block 410, a customer of the service site is notified of the open-switch event. In an example, the notification may be based at least in part on the determining of block 408, and may be performed by sending a message (e.g., voice mail, text message, email message, or other communication) to a mobile device, smart home device (e.g., home hub device), or other computing device of the customer. Accordingly, a number of communication technologies may be used to notify the customer. In examples, one or more of: a mobile phone; Email; SMS; IHDs; a smart meter display may be used. Additionally, the headend or central data center (e.g., servers 102 of FIG. 1) may also be notified. Any appropriate communication technology may be used, such as: cellular; Zigbee; HAN, BLE, PLC, RF Mesh Network; and others.

The notification may additionally or alternatively be output by the smart meter and/or one or more breakers in the form of an audible or visible alert. The notification allows the customer to restore service by resetting the circuit breaker box and turning off one or more appliances or devices. In an example utilizing an electrically resettable circuit breaker, block 410 may be replaced and/or supplemented by a circuit reset. As seen in block 208 of FIG. 2, the circuit breaker may be reset by the utility company and/or by the smart meter with or without intervention by the customer.

FIG. 5 shows a first example method 500 for learning circuit characteristics within an electricity service site, and for managing MCB devices. The method 500 may be performed by the smart meter 106 described in FIGS. 1-3.

In a first example: disaggregation of the consumption of various appliances and other devices allows the identification of some or all of the devices operating at any given time. This process may take some time, as consumption data is measured and recorded, and the overall load changes by different amounts as devices are turned on and off. Also over time, one or more circuit breaker switches will “trip” or open. Each circuit breaker switch protects a respective circuit from excessive power consumption. The sum of the loads (of one or more appliances or other devices) on the opened circuit can recognized as the total load is reduced in response to the open-switch event. Accordingly, devices whose aggregate load matches the load lost in the open-switch event may be recognized by use of the disaggregation. Thus, the disaggregation process identifies the appliances and devices by the consumption rate of each device. The occasional tripped breaker switch helps to identify the circuit—from among a plurality of circuits of the circuit breaker box—used by devices recognized in the disaggregation.

In a second example: by disaggregating the load of the smart electricity meter, the power consumption (or current use) of the appliances of the service site is learned. On occasion, when a breaker trips, the smart electricity meter will measure a load reduction. If that load reduction is approximately equal to the sum of the power of one or more of the known appliances, it is possible that those appliances are connected to the circuit of the breaker box associated with the tripped breaker switch. After a threshold period of time, if disaggregation fails to identify the activity of the one or more of the known appliances, this can be considered to be evidence of an open-circuit event.

In a third example: a smart circuit breaker box or a miniature circuit breaker (MCB) may report the identity of the tripped breaker switch and/or circuit to the smart meter 106. The customer can be advised of the concern that the breaker needs to be reset, and one or more of the appliances of the circuit should be turned off.

At block 502, a load measured by the smart metering device is disaggregated to determine one or more constituent devices of the load. Thus, disaggregation identifies one or more devices, the sum of whose consumption is the load measured by the smart metering device.

At block 504, an association between the two or more constituent devices and respective circuits of a circuit breaker box of the service site is learned. In an example, the association may be based at least in part on simultaneous removal (e.g., such as by an open-switch event at the circuit breaker box) of loads associated with the two or more constituent devices from load measured by the smart metering device).

At block 506, an open-switch event is determined to have occurred. In an example, the learned association of block 504 and/or the techniques of block 408 may be used to identify the open-switch event. In an example, the simultaneous removal of the sum of the two (or more) loads associated with two (or more) devices is indicative of a tripped breaker, and not two (or more) devices being turned off at exactly the same time.

At block 508, responsive to an open-switch event, smart metering devices (e.g., equipped with distributed intelligence software) can communicate with neighboring meters to determine the extent of fault or power surge and isolate affected area, thereby providing utility companies with more information to enable them to respond more effectively and minimize downtime.

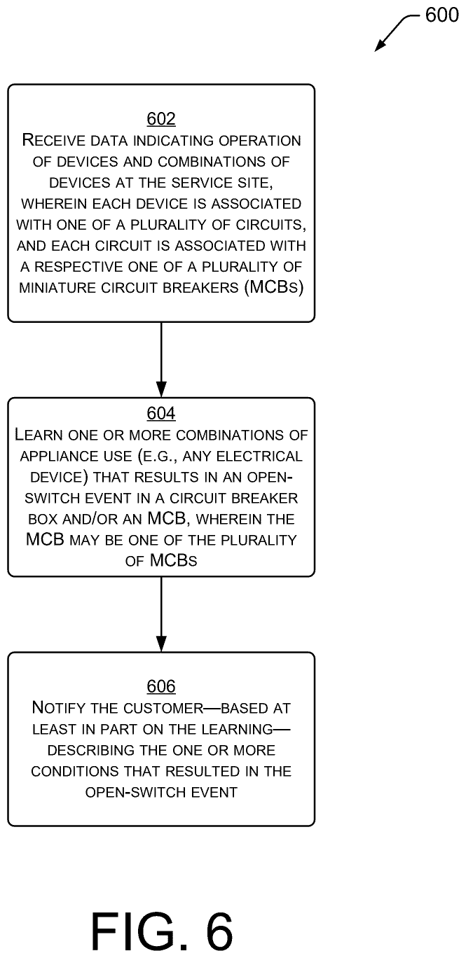

FIG. 6 shows an example method 600 for learning circuit characteristics within an electricity service site, and for managing MCB devices. The method 600 may be performed by the smart meter 106 and components seen in FIG. 3. The method 600 utilizes data indicating operation of devices (e.g., appliances) and combinations of devices, wherein the data is associated with circuits of the circuit breaker box and/or associated with miniature circuit breaker devices. A learning algorithm (e.g., machine learning and/or artificial intelligence) learns one or more conditions that result in an open-switch event. Such events may be combinations of appliances and/or devices that, when operated simultaneously, result in an open-switch event. This information is passed on to the customer at the service site, so that the inconvenience of an open-switch event can be avoided.

At block 602, data is received indicating operation of devices and combinations of devices at the service site. In an example, the data shows at least some associations between devices and: their respective operational power consumption; their respective connectivity to circuits within the circuit breaker box; and/or their respective association with one of a plurality of miniature circuit breakers (MCBs).

At block 604, combinations of appliance use that result in an open-switch event are learned. The learning may be performed by operation of an algorithm and/or machine learning model. The open-switch event may be in an MCB or in the circuit breaker box. In an example, a “learning process” enables the smart meter to selectively turn on and off the circuits of the service site in order to determine which loads are associated with each circuit. In the example, the circuit breaker box could be remotely controlled to open and/or close switches to enable circumstances that would make the learning process possible and/or more rapid. In a further example, using a machine learning model, individual appliance behavior can be determined by analyzing meter data. Such learning processes use an AI algorithm and a database of appliance characteristics to determine what loads are being switched on. For example, a garage door opener will show a large in-rush current as the motor is started, followed by less than a minute of approximately constant power consumption, followed by a full stop. Models may be trained to recognize anomalies (e.g., a circuit breaker open-switch event) in multiple circuits.

At block 606, the customer is notified—based at least in part on the learning—of one or more conditions that have resulted, and/or will result, in open-switch event(s). Accordingly, the customer may avoid the inconvenience of an open-switch event in the future.

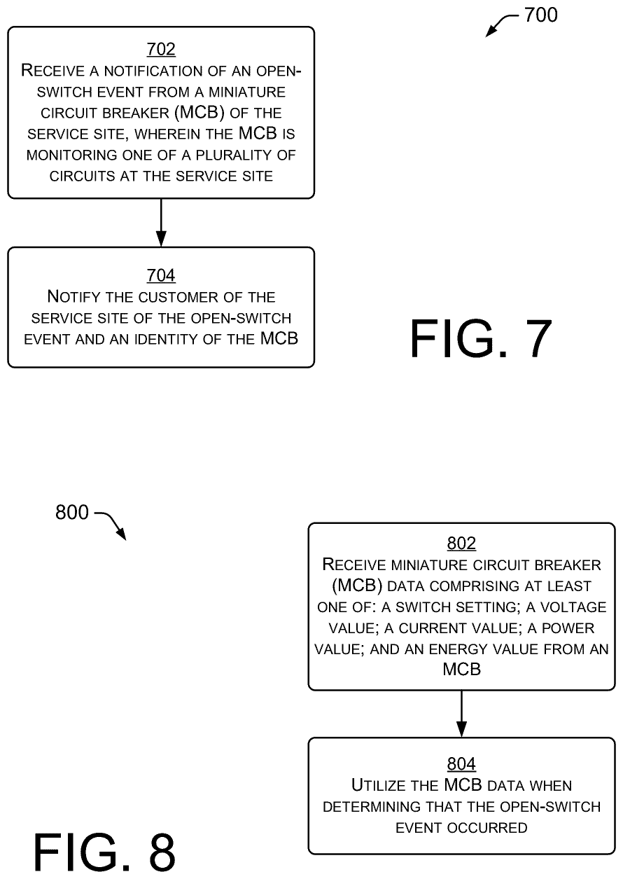

FIG. 7 shows a further method 700 for responding to, and providing notice of, MCB open-switch events. The method 700 may be performed by the smart meter 106 and components seen in FIG. 3. At block 702, a notification of an open-switch event is received (e.g., at the smart meter 106) from a miniature circuit breaker (MCB) of the service site. In an example, the MCB is monitoring one of a plurality of circuits at the service site. Thus, the MCB will create an open-switch event if current flow exceeds a maximum allowed value and send a notification to the smart meter 106. At block 704, the customer of the service site is notified of the open-switch event. In some examples, the customer is also notified of an identity of the MCB having an open-switch event.

In an example, if a circuit at a service site loses power (e.g., breaker trips) but other circuits at the service site have power, then the smart meter can notify the customer that the outage is due to a tripped breaker. Moreover, the smart meter can determine a specific breaker switch that has tripped and include that information in the notification.

FIG. 8 shows further example method 800 for responding to, and providing notice of, MCB open-switch events. The method 800 may be performed by the smart meter 106 and components seen in FIG. 3. At block 802, miniature circuit breaker (MCB) data, sent by an MCB, is received at the smart meter 106. In an example, the data may include at least one of: a switch setting (i.e., the setting of the breaker switch of the MCB); a voltage value; a current value; a power value; and an energy value. At block 804, the MCB data is utilized by the smart meter 106 when determining that (or checking for) the open-switch event occurred.

### Integration with Other Systems

Integration with Grid Management Systems: Smart meters can be integrated with advanced grid management systems to enable efficient fault detection, isolation, and restoration. By detecting circuit breaks at the smart meter level, utilities can gain insights into the health of the electrical grid and can better coordinate grid operations and optimize response strategies.

Fault isolation: When a circuit break occurs, smart meters equipped with DI can communicate with neighboring meters to determine the extent of fault or power surge and isolate affected area, allowing utilities to respond more effectively and minimize downtime.

Dynamic Reconfiguration and load balancing: Smart meters with DI can support dynamic reconfiguration of the grid in response to circuit breaks. They can also support can support load balancing functionalities to optimize electricity distribution across the grid. By analyzing data locally and communicating with other meters in the network, smart meters can help utilities reconfigure the grid to restore power to unaffected areas while isolating the faulted section. In the event of a circuit break, smart meters can also support utilities to dynamically adjust load distribution to prevent overloading in other parts of the grid. These steps improve grid resilience and minimize electricity supply disruptions for consumers.

When a circuit break occurs, smart meters equipped with distributed intelligence (DI) can communicate with neighboring meters to determine the extent of fault or power surge and isolate affected area, allowing utilities to respond more effectively and minimize downtime.

### Conclusion

Although the subject matter has been described in language specific to structural features and/or methodological actions, it is to be understood that the subject matter defined in the appended claims is not necessarily limited to the specific features or actions described. Rather, the specific features and actions are disclosed as exemplary forms of implementing the claims.

The words comprise, comprises, and/or comprising, when used in this specification and/or claims do not preclude the presence or addition of one or more other features, devices, techniques, and/or components and/or groups thereof.

1. A method of operating a smart metering device, comprising:
measuring a voltage value of a transformer-side of a service site;
measuring at least one of a power value or a current value of a circuit of the service site;
determining, by the smart metering device and based at least in part on the voltage value being non-zero and the at least one of the power value or the current value of the circuit being zero, that an open-switch event occurred; and
notifying a customer of the service site of the open-switch event, wherein the notifying is based at least in part on the determining.

2. The method of claim 1, additionally comprising:
disaggregating a load measured by the smart metering device to determine two or more constituent devices of the load; and
learning an association between the two or more constituent devices and the circuit;
wherein the determining that the open-switch event occurred is additionally based at least in part on the association.

3. The method of claim 1, additionally comprising:
disaggregating a load measured by the smart metering device to determine two or more constituent devices of the load; and
associating the two or more constituent devices with the circuit, wherein the associating is based at least in part on simultaneous removal of loads associated with the two or more constituent devices from load measured by the smart metering device;
wherein the determining that the open-switch event that occurred is additionally based at least in part on simultaneous removal of loads associated with the two or more constituent devices from load measured by the smart metering device.

4. The method of claim 1, additionally comprising:
receiving data indicating operation of devices and combinations of devices at the service site, wherein each device is associated with the circuit or one or more other circuits of a circuit breaker box, and at least one of the circuit or the one or more other circuits of the circuit breaker box is associated with a respective miniature circuit breakers (MCBs);
learning one or more combinations of appliance use that result in an open switch in an MCB; and
based at least in part on the learning, notifying the customer of one or more potential causes of one or more openings of one or more breaker switches.

5. The method of claim 1, additionally comprising:
receiving a notification of an open-switch event from a miniature circuit breaker (MCB) of the service site, wherein the MCB is monitoring the circuit or one or more other circuits at the service site,
wherein notifying the customer of the service site additionally comprises notifying the customer of the open-switch event and an identity of the MCB.

6. The method of claim 1, additionally comprising:
receiving miniature circuit breaker (MCB) data comprising at least one of: a switch setting; a voltage value; a current value; a power value; and an energy value from an MCB; and
utilizing the MCB data when determining that the open-switch event occurred.

7. The method of claim 1, wherein notifying the customer comprises:
sending a signal to a circuit breaker device to reset the circuit breaker device.

8. The method of claim 1, wherein the method is performed based at least in part on actions comprising:
receiving a command to perform the method sent by a mobile device of the customer; or
receiving a command to perform the method sent by an electrical utility company.

9. A smart metering device, comprising:
a processor;
one or more memory devices in communication with the processor;
statements, defined in the one or more memory devices, which when executed by the processor perform actions comprising:
measuring a voltage value of a transformer-side of a service site;
measuring at least one of a power value or a current value of a circuit of the service site;
determining, by the smart metering device and based at least in part on the voltage value being non-zero and the at least one of the power value or the current value of the circuit being zero, that an open-switch event occurred; and
notifying a customer of the service site of the open-switch event, wherein the notifying is based at least in part on the determining.

10. The smart metering device as recited in claim 9, wherein the actions additionally comprise:
disaggregating a load measured by the smart metering device to determine two or more constituent devices of the load; and
learning an association between the two or more constituent devices and the circuit;
wherein the determining that the open-switch event occurred is additionally based at least in part on the association.

11. The smart metering device as recited in claim 9, wherein the actions additionally comprise:
disaggregating a load measured by the smart metering device to determine two or more constituent devices of the load; and
associating the two or more constituent devices with the circuit, wherein the associating is based at least in part on simultaneous removal of loads associated with the two or more constituent devices from load measured by the smart metering device;
wherein the determining that the open-switch event that occurred is additionally based at least in part on simultaneous removal of loads associated with the two or more constituent devices from load measured by the smart metering device.

12. The smart metering device of claim 9, wherein the actions additionally comprise:
receiving data indicating operation of devices and combinations of devices at the service site, wherein each device is associated with the circuit or one or more other circuits of a circuit breaker box, and at least one of the circuit or the one or more other circuits of the circuit breaker box is associated with a respective miniature circuit breakers (MCBs);
learning one or more combinations of appliance use that result in an open switch in an MCB; and
based at least in part on the learning, notifying the customer of one or more potential causes of one or more openings of one or more breaker switches.

13. The smart metering device of claim 9, wherein the actions additionally comprise:
receiving a notification of an open-switch event from a miniature circuit breaker (MCB) of the service site, wherein the MCB is monitoring the circuit or one or more other circuits at the service site,
wherein notifying the customer of the service site additionally comprises notifying the customer of the open-switch event and an identity of the MCB.

14. The smart metering device of claim 9, wherein the actions additionally comprise:
receiving miniature circuit breaker (MCB) data comprising at least one of: a switch setting; a voltage value; a current value; a power value; and an energy value from an MCB; and
utilizing the MCB data when determining that the open-switch event occurred.

15. One or more non-transitory computer-readable media storing computer-executable instructions that, when executed by one or more processors, configure a smart metering device to perform actions comprising:
measuring a voltage value of a transformer-side of a service site;
measuring at least one of a power value or a current value of a circuit of the service site;
determining, by the smart metering device and based at least in part on the voltage value being non-zero and the at least one of the power value or the current value of the circuit being zero, that an open-switch event occurred; and
notifying a customer of the service site of the open-switch event, wherein the notifying is based at least in part on the determining.

16. One or more computer-readable media as recited in claim 15, wherein the actions additionally comprise:
disaggregating a load measured by the smart metering device to determine two or more constituent devices of the load; and
learning an association between the two or more constituent devices and the circuit;
wherein the determining that the open-switch event occurred is additionally based at least in part on the association.

17. One or more computer-readable media as recited in claim 15, wherein the actions additionally comprise:
disaggregating a load measured by the smart metering device to determine two or more constituent devices of the load; and
associating the two or more constituent devices with the circuit, wherein the associating is based at least in part on simultaneous removal of loads associated with the two or more constituent devices from load measured by the smart metering device;
wherein the determining that the open-switch event that occurred is additionally based at least in part on simultaneous removal of loads associated with the two or more constituent devices from load measured by the smart metering device.

18. One or more computer-readable media as recited in claim 15, wherein the actions additionally comprise:
receiving data indicating operation of devices and combinations of devices at the service site, wherein each device is associated with the circuit or one or more other circuits of a circuit breaker box, and at least one of the circuit or the one or more other circuits of the circuit breaker box is associated with a respective miniature circuit breakers (MCBs);
learning one or more combinations of appliance use that result in an open switch in an MCB; and
based at least in part on the learning, notifying the customer of one or more potential causes of one or more openings of one or more breaker switches.

19. One or more computer-readable media as recited in claim 15, additionally comprising:
receiving a notification of an open-switch event from a miniature circuit breaker (MCB) of the service site, wherein the MCB is monitoring the circuit or one or more other circuits at the service site,
wherein notifying the customer of the service site additionally comprises notifying the customer of the open-switch event and an identity of the MCB.

20. One or more computer-readable media as recited in claim 15, wherein the actions additionally comprise:
receiving miniature circuit breaker (MCB) data comprising at least one of: a switch setting; a voltage value; a current value; a power value; and an energy value from an MCB; and
utilizing the MCB data when determining that the open-switch event occurred.
